(19) United States
(12) Patent Application Publication
(10) Pub. No.: US 2025/0335644 A1
(43) Pub. Date: Oct. 30, 2025

(54) AUTOMATIC DESIGN METHOD AND DEVICE FOR MODULAR COLD- FORMED THIN-WALLED STEEL STRUCTURE

(71) Applicant: China Southwest Architectural Design and Research Institute Co., Ltd, Chengdu (CN)

(72) Inventors: Yifeng LIU, Chengdu (CN); Xue JIANG, Chengdu (CN); Guangpo ZHAO, Chengdu (CN); Qianyi SONG, Chengdu (CN); Meilin YE, Chengdu (CN); Shujun BAI, Chengdu (CN); Qiuji LI, Chengdu (CN); Bo DONG, Chengdu (CN)

(21) Appl. No.: 19/007,347

(22) Filed: Dec. 31, 2024

(30) Foreign Application Priority Data
Apr. 26, 2024 (CN) 202410511641.7

(51) Int. Cl. G06F 30/13

(52) U.S. Cl. CPC G06F 30/13

(57) ABSTRACT

An automatic design method of a modular cold-formed thin-walled steel structure, including: a minimum length of a first shear wall is obtained from a pre-designed simplified seismic design calculation table according to the number of floors and a type of cladding panels of a to-be-designed building, and a seismic fortification intensity; the length of a shear wall without openings is an actual length of the shear wall; if the actual length is less than or equal to the minimum length of the first shear wall, the shear bearing capacity does not meet requirements, and the shear bearing capacity is increased; if the actual length is greater than the minimum length of the first shear wall, the shear bearing capacity meets the requirements, and the final shear wall length is obtained; and the design of the modular cold-formed thin-walled steel structure is completed according to the final shear wall length.

### CROSS REFERENCE TO RELATED APPLICATIONS

This application claims foreign priority of Chinese Patent Application No. 202410511641.7, filed on Apr. 26, 2024 in the China National Intellectual Property Administration, the disclosures of all of which are hereby incorporated by reference.

### TECHNICAL FIELD

The present disclosure relates to the technical field of automatic design of light steel structures in the construction industry, in particular to an automatic design method and device for a modular cold-formed thin-walled steel structure.

### BACKGROUND

Based on the traditional cold-formed thin-walled steel structure system, the modular cold-formed thin-walled steel structure system introduces modular concepts, uses general standardized modular units, and prefabricates and assembles wall modules, floor modules, and roof modules in the factory, and then the wall modules, floor modules, and roof modules were transported to the site and connected through connecting bolts, thereby realizing assembly between the different modules. The modular cold-formed thin-walled steel structure system can greatly improve industrialization, productization, assembly level.

The calculation software of the existing cold-formed thin-walled steel structure does not have a calculation module for the modular cold-formed thin-walled steel structure system, and the calculation method for the modular cold-formed thin-walled steel structure system is also blank in the industry. At present, in the actual design process, the designer can only calculate and check the force of each keel in clumsy way according to the existing national standard specifications, resulting in large workload, being time-consuming, high error rate, and poor calculation results in economy.

In the context of vigorously advocating the industrialization and assembly of construction, the cold-formed thin-walled steel structure as an environment-friendly structural system, will be vigorously promoted, so there is a great need for proposing a more efficient and simple automatic design and calculation method for the modular cold-formed thin-walled steel structure system.

### SUMMARY

In view of the deficiencies in the prior art, this application provides an automatic design method and device for a modular cold-formed thin-walled steel structure in order to make the design of the modular cold-formed thin-walled steel structure system more efficient and simpler, and lay the foundation for engineering application and promotion of the modular cold-formed thin-walled steel structure system.

Technical solutions of this application are described as follows.

This application provides an automatic design method of a modular cold-formed thin-walled steel structure, comprising:

(a) obtaining a minimum length of a first shear wall from a pre-designed simplified seismic design calculation table according to the number of floors of a to-be-designed building, a seismic fortification intensity, and a type of cladding panels of the to-be-designed building;

(b) determining a length of a shear wall without a door opening or a window opening, which is an actual length of the shear wall;

(c) comparing the minimum length of the first shear wall with the actual length of the shear wall:

if the actual length of the shear wall is less than or equal to the minimum length of the first shear wall, a shear bearing capacity does not meet requirements, and the shear bearing capacity needs to be increased; and

if the actual length of the shear wall is greater than the minimum length of the first shear wall, the shear bearing capacity meets the requirements, and a final length of the shear wall is obtained; and

(d) completing a design of the modular cold-formed thin-walled steel structure according to the final shear wall length.

In an embodiment, the pre-designed simplified seismic design calculation table comprises the seismic fortification intensity, the number of floors, the type of cladding panels, and the minimum length of the first shear wall, and the minimum length of the first shear wall is a sum of the average floor area multiplied by a first coefficient and the average plane wall length multiplied by a second coefficient.

In an embodiment, the average floor area of the building is calculated by dividing the building area with the number of floors; and the average plane wall length is calculated by dividing the sum of the plane wall lengths of all the floors of the building with the number of floors.

In an embodiment, the design method of the pre-designed simplified calculation table for seismic design comprises: the common structural levels of the cold-formed thin-walled steel structure system is summarized, where the floor constant load is taken as 2.0 kN/m2, the wall constant load is taken as 1.5 kN/m2, the variable load is obtained according to GB50009-2012 “Load code for the design of building structures”, and the floor height is taken as 3 m; based on the average floor area and the average plane wall length of the building, the total structural equivalent gravity load is calculated by using the bottom shear method; and according to the total structural equivalent gravity load, the minimum length of the first shear wall is calculated.

In an embodiment, the shear bearing capacity is increased by at least one of methods (1)-(3): (1) adjusting a household arrangement, and adding a new shear wall; (2) changing a single-side cladding panel of the shear wall to a double-side cladding panel without changing the household arrangement; and (3) changing the type of cladding panels, and choosing a cladding panel material with higher shear bearing capacity.

In an embodiment, the automatic design method further comprises: obtaining the number of floors of the to-be-designed building, a wind pressure, and a type of cladding panels of the to-be-designed building; obtaining a minimum length of a second shear wall from a pre-designed simplified wind-resistant design calculation table; based on the minimum length of the first shear wall and the minimum length of the second shear wall, obtaining the minimum length of the shear wall; and comparing the minimum length of the shear wall with the actual length of the shear wall to obtain the final length of the shear wall.

In an embodiment, the step of “based on the minimum length of the first shear wall and the minimum length of the second shear wall, obtaining the minimum length of the shear wall” comprises: obtaining envelope values of the minimum length of the first shear wall and the minimum length of the second shear wall.

In an embodiment, the pre-designed simplified wind-resistant design calculation table comprises the wind pressure, the number of floors, the type of cladding panels, and the minimum length of the first shear wall; and the minimum length of the second shear wall is a product of multiplying a third factor with the width of the to-be-designed building in a direction of the shear wall.

In an embodiment, the minimum length of the shear wall is obtained from the pre-designed wind-resistant design simplified calculation table according to calculation provisions for wind loads in GB50009-2012 “Load code for the design of building structures”.

This application also provides an automatic design device, comprising:
at least one processor;
a memory; and
a program instruction;
wherein the memory is communicatively connected to the at least one processor; the program instruction is stored in the memory and is configured to be executed by the at least one processor, and the at least one processor is configured to execute the program instruction to implement the automatic design method above.

Compared to the prior art, this application has the following beneficial effects.

This application pre-designs a simplified calculation table for seismic design, so that the minimum length of the shear wall can be found directly according to the conditions, then the actual length of the shear wall can be compared with the minimum length of the shear wall to judge the shear bearing capacity, so as to obtain the final length of the shear wall. Based on the final length of the shear wall, the modular cold-formed thin-walled steel structure design can be completed. The method is simple, has high computational efficiency, and lowers design threshold, is convenient for professional or non-professionals to use, is easy to forward design and reverse checking, and improves design efficiency.

### BRIEF DESCRIPTION OF THE DRAWINGS

FIG. 1 is a flow chart of an automatic design method for a modular cold-formed thin-walled steel structure according to Embodiment 1 of the present disclosure;

FIG. 2 is a flowchart of a length design method of a shear wall based on the modular cold-formed structure system in Embodiment 1 of the present disclosure;

FIG. 3 is a first-floor floor plan according to Embodiment 2 of the present disclosure; and

FIG. 4 is a second-floor floor plan according to Embodiment 2 of the present disclosure.

### DETAILED DESCRIPTION OF THE EMBODIMENTS

The present disclosure is described in detail below in conjunction with the accompanying drawings.

The present disclosure will be further described in detail below in conjunction with the accompanying drawings and embodiments to understand the objects, technical solutions, and advantages of the present disclosure more clearly. It should be understood that the embodiments described herein are only used to illustrate and explain this application, which are not intended to limit the disclosure.

### Embodiment 1

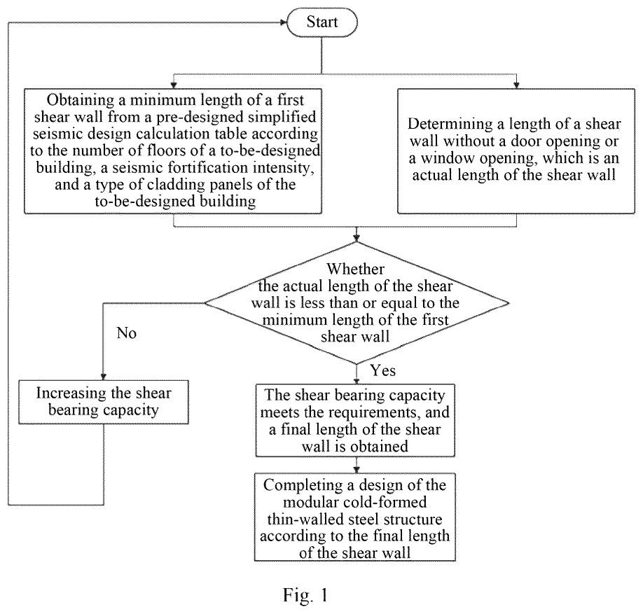

Referring to FIG. 1, an automatic design method of a modular cold-formed thin-walled steel structure includes the following steps (a)-(d).

(a) A minimum length of a first shear wall is obtained from a pre-designed simplified seismic design calculation table according to the number of floors of a to-be-designed building, a seismic fortification intensity, and a type of cladding panels of the to-be-designed building.

(b) The length of a shear wall without a door opening or a window opening is determined and is an actual length of the shear wall.

(c) The minimum length of the first shear wall is compared with the actual length of the shear wall.

If the actual length of the shear wall is less than or equal to the minimum length of the first shear wall, the shear bearing capacity does not meet requirements, and the shear bearing capacity needs to be increased.

If the actual length of the shear wall is greater than the minimum length of the first shear wall, the shear bearing capacity meets the requirements, and the final length of the shear wall can be obtained.

(d) The design of the modular cold-formed thin-walled steel structure will be completed according to the final length of the shear wall.

For the low-level cold-formed thin-walled steel structure, the main bearing components are the walls, and the type of load includes gravity (vertical load) and wind or earthquake (horizontal load). The gravity (vertical load) is borne by all the cold-formed vertical keel, while the wind or earthquake (horizontal load) need to be borne by the shear wall. The core of the calculation method is the calculation of shear wall, when the length calculation of the shear wall is completed, the overall design of the cold-formed structure is completed.

As an alternative, the form used to find the minimum length of the shear wall is not the pre-designed simplified seismic design calculation table, but a pre-designed simplified wind-resistant design calculation table. The type of the selected table is determined by the geographic location of the to-be-designed house/to-be-designed building. When the to-be-designed house is located in the seismic zone, the pre-designed simplified seismic design form will be used.

The simplified seismic design calculation table and the simplified wind-resistant design calculation table are obtained according to the structural level of the cold-formed thin-walled steel structure system. The design ideas of the simplified seismic design calculation table and the simplified wind-resistant design calculation table are as follows.

The shear wall of the cold-formed thin-walled steel structure are designed to resist shear forces by working together with the cladding panels and cold-formed thin-walled steel frame. The design method of the minimum length of the shear wall during seismic design in Table 1 is based on the bottom shear method in GB5011-2010 “Code for seismic design of buildings”. The structural level of the cold-formed thin-walled steel structure system is complex. Through studying multiple cold-formed thin-walled steel village residential projects, we have summarized the typical and common structural levels of the cold-formed system and taken the floor constant load of 2.0 kN/m2 and the wall constant load of 1.5kN/m². The variable load is obtained according to the GB50009-2012 “Load code for the design of building structures”, and the floor height is 3 m. Table 1 “minimum length of the shear wall for seismic design” is finally obtained according to the bottom shear method.

The general idea of obtaining the minimum length of the shear wall is as follows: based on the average floor area A and the average plane wall length L of the building, the total structural equivalent gravity load Geq is calculated by the bottom shear method; since the total structural equivalent gravity load Geq is calculated, the minimum length of the shear wall can be converted according to the codes. There is no method in the prior art for calculating the total structural equivalent gravity load Geq using the average floor area A and the average plane wall length L of the building. In the present disclosure, such a conversion between the total structural equivalent gravity load Geq and the minimum length of the shear wall is made, so that the obtained minimum length of the shear wall can be expressed by the calculation formulas for the average floor area A and the average plane wall length L of the building. Further, the minimum lengths of shear walls at different seismic fortification intensities, the number of floors and cladding panels are obtained, which facilitates the calculation in the subsequent design and makes the calculation easier compared to the prior art.

The method for obtaining the minimum length of the shear walls in seismic design in table is illustrated as follows.

Take the second column of the first row in the table of “minimum length of shear wall in seismic design” as an example, i.e., a three-floor building in the area with the seismic fortification intensity of 6 degrees is designed. When the 9 mm single-sided oriented strand board is used as the cladding panel of the combined wall of the cold-formed thin-walled steel structure, the minimum length of the second-floor shear wall is expressed as 0.043A+0.072L (m), where A represents the average floor area (m2) of the building, A=the building area/the number of floors; L represents the average plane wall length (m), and L=the sum of the plane wall lengths of all floors of the building/the number of floors. The steps to derive the minimum length of the second-floor shear wall as 0.043A+0.072L (m) are as follow.

In the first step, through studying several cold-formed thin-walled steel village residential projects, the typical common structural levels of the cold-formed system are summarized. The floor constant load is taken as 2.0 kN/m², the wall constant load is taken as 1.5 kN/m², and the floor height is 3 m, so the gravity load of the second floor is 3 A+4.5 L (kN).

In the second step, based on the bottom shear method, the total structural equivalent gravity load can be derived as G_{eq}=5.95A+9.5625L (kN), and in turn the standard value of the total structural horizontal seismic action as F_{EK}=0.275A+0.442L (kN), and the standard value of the horizontal seismic action of the second floor, F2-0.138A+0.197L (kN) are further obtained.

The third step, according to chapter 5 and chapter 8 of JGJ 227-2011 “Technical specification for low-rise cold-formed thin-walled steel buildings”, in the seismic fortification zone, the shear force per unit length of the shear wall is expressed as

$${S}_{E} = \frac{{V}_{j}}{{L}_{j}} \leq {S}_{h} / {r}_{RE} .$$

Where Vⱼ represents the horizontal shear force in kN beared by the shear wall; Lⱼ represents the length (m) of the shear wall; Sₕ represents the design value (kN/m) of the shear bearing capacity per unit length of the shear wall, and r_{RE} represents the seismic coefficient of the shear bearing capacity, taken as 0.9. The length of the shear wall is expressed as

$${L}_{j} \geq {r}_{RE} \frac{{V}_{j}}{{S}_{h}} .$$

The horizontal shear force Vⱼ beared by the shear wall is obtained by multiplying the standard value F₂ of the horizontal seismic action of the second floor by the partial coefficient of the design value. According to the types of cladding panels, Sₕ per unit length of the 9 mm single-sided oriented strand board is obtained from technical specification, and Sₕ=6.4 kN/m. An amplification coefficient in the technical specification is considered, and based on the formula of

$${L}_{j} = {r}_{RE} \frac{{V}_{j}}{{S}_{h}} ,$$

the minimum length L₁=0.043A+0.072L (m) of the second-floor shear wall can be obtained.

Considering that the plan area and wall length of each floor of low-rise village houses are different due to layout design, in Table 1, A represents the average floor area of the building, i.e., the total floor area/the number of floors; and L represents the average plane wall length, i.e., (the sum of the lengths of all walls on all floors of the building)/the number of floors. A and L are averaged for more accurately determining the representative values of gravity loads, thereby determining the shear wall lengths for seismic resistance. In Table 1, the unit of the A is square meter (m²), and the unit of the L is meter (m), only numerical value of A and L are brought into the table, and the parameters in the table have considered the conversion of the unit.

### Table 1 Minimum Length (m) of Shear Wall for Seismic Design

In Table 1, A refers to the average floor area of the building (m2), A=the building area/number of floors; L refers to the average plane wall length (m), L=(the sum of the plane wall lengths of all the floors of the building)/number of floors. 1F refers to the top floor of a single-floor building, two-floor building, or three-floor building. 2F refers to the ground floor of the two-floor building or the second floor of the three-floor building. 3F refers to the ground floor of the three-floor building. The coefficient in front of the average floor area A of the building is the first coefficient, and the coefficient in front of the average plane wall length is the second coefficient.

### Table 2 Minimum Length (m) of Shear Wall for Wind-Resistant Design (m)

In Table 2, B refers to the width (m) of the building perpendicular to the direction of the shear wall. If the width of the second and above floor differs greatly from that of the first floor, B=(the sum of the widths of the buildings on all floors of the building)/(number of floors). In Table 2, IF refers to the top floor of the single-floor building, two-floor building, or three-floor building. 2F refers to the ground floor of the two-floor building or the second floor of the three-floor building. 3F refers to the ground floor of the three-floor building. The coefficient in front of the width B (m) of the building perpendicular to the direction of the shear wall is the third coefficient.

In Table 2, when performing wind-resistant design, the minimum length of the shear wall is based on the calculation provisions for wind loads in GB50009-2012 “Load code for the design of building structures”, considering different values of wind pressure and different number of floors, three common cladding panels can be selected, and the minimum length of the shear wall in wind-resistant design is obtained from Table 2. There is only one variable parameter B in Table 2, B is the width of the building perpendicular to the direction of the shear wall. When the width of the second floor and above differs greatly from that of the first floor, B=the sum of the widths of the buildings on all floors of the building/number of floors. The shear wall length of the cold-formed thin-walled steel structure system in both directions (X-direction, Y-direction) should not be less than values in Table 1 or Table 2, and should take envelope values in the two cases of seismic and wind resistance. The envelope values mean to take the maximum or the most unfavorable situation, indicating that the shear wall length of the cold-formed thin-walled steel structure system in both directions (X-direction, Y-direction) will be calculated according to the most secure results. The simplified design method for the shear wall length of the cold-formed thin-walled steel structural system for low-rise village houses proposed in this embodiment reduces the design threshold, is simple to operate; and the shear wall length can be estimated after the building type is determined, which is conducive to the checking of the plan wall arrangement of the building, and is convenient for the use of non-professionals.

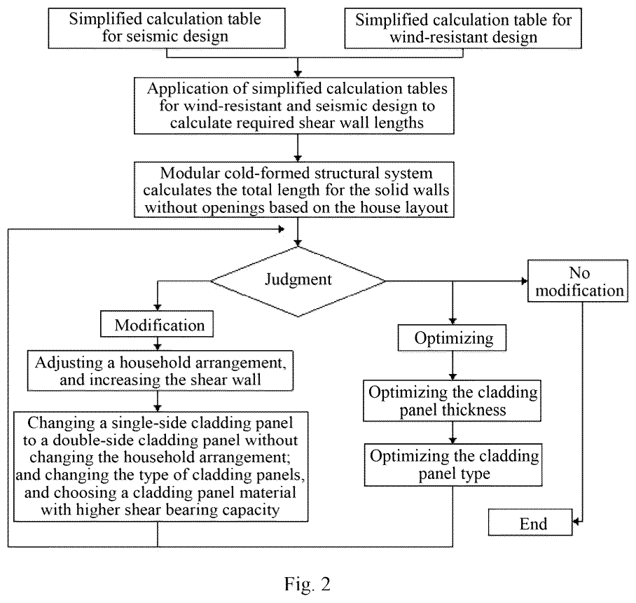

Table 1 and Table 2 are mainly for the traditional cold-formed thin-walled steel structure system, which has a wide range of application and is suitable for the modular cold-formed structural system. In the modular cold-formed structural system, all modules with openings are categorized as non-shear walls, and the rest of the wall modules without openings are considered as shear walls. Given that the modular cold-formed structural system is based on the innovative evolution of the traditional cold-formed structural system, FIG. 2 shows the flow chart of the design method of the shear wall length based on the modular cold-formed structural system. The relationship and application of two design methods for the shear wall length are described in detail, with the following steps (1)-(5). (1) The shear wall length required in each direction under wind and seismic action are calculated using the simplified design methods in Tables 1 and 2. (2) The wall modules without openings in each direction are searched, and the actual length L of the shear wall is calculated using the design method of the shear wall length of the modular cold-formed structural system. All the walls bear gravity. The wall modules are classified as the shear wall and the non-shear wall. Wall modules with door and window openings are the non-shear walls. The wall modules without door or window openings are the shear walls. Given the layout of the house, the length of the shear wall without door or window openings is determined, that is, obtaining the actual length of the shear wall L. (3) Two kinds of wall lengths obtained in steps (2) and (1) are compared to determine whether the shear bearing capacity meets the requirements. (4) If the actual length in step (2)≤the length in step (1), it means that the shear bearing capacity does not meet requirements, the shear bearing capacity can be increased by (1) adjusting the household arrangement, and adding the shear wall; or changing the single-side cladding panel of the wall to the double-side cladding panel without changing the household arrangement; or (3) changing the type of cladding panels, and selecting the cladding panel material with higher shear bearing capacity; and (5) if the actual length in step (2)>the length in step (1), no modification needs to be made, or the wall panel system can be optimized and adjusted according to the degree of surplus, for example, the thickness and type of cladding panel are adjusted.

### Embodiment 2

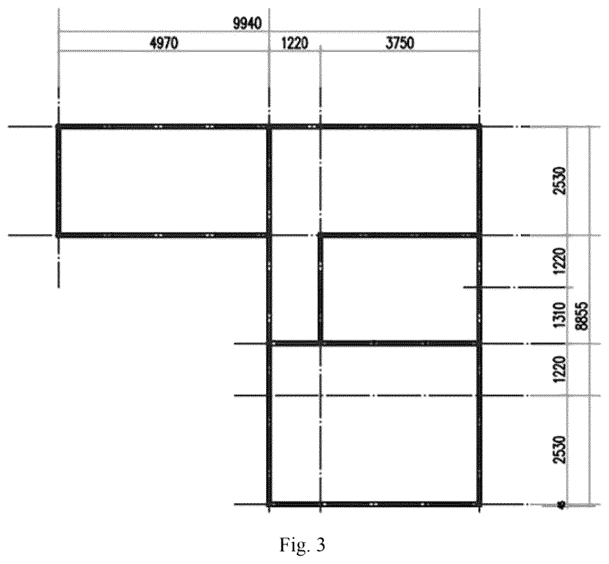

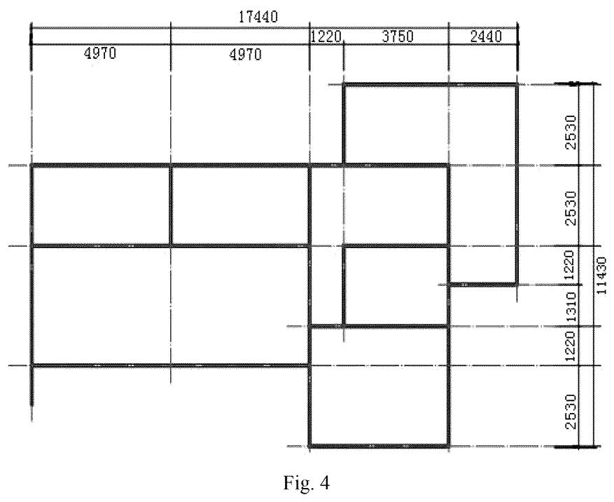

An actual case would be used to illustrate the effect of the practical use of the automatic design method the modular cold-formed thin-walled steel structure. The first-floor floor plan of the project was shown in FIG. 3, and the second-floor floor plan was shown in FIG. 4. In FIGS. 3 and 4, the numerical values were in millimeters, and the project profile was shown in Table 3.

TABLE 3
Project profile table

| Item | Parameter |
|---|---|
| Total floor area | 181.89 m |
| Number of floors | 2 |
| Building height | 6.972 m |
| Structure type | Modular cold-formed thin-wall steel |
| | structure system |
| Seismic fortification | 7 degrees (0.10 g) |
| intensity | |
| Fire-resistance grade | Level 3 |

The house layout was modularly divided, including non-standard modules. There were eight types of wall modules in this project, with a total of 87 wall modules and a total wall length of 143.24 m. Among them, the first three types of modules with the largest number are numbered W-1, W-3 and W-7, with the total of 77 and the wall length of 129.32 m, and the first three types of modules accounted for 90.28%, as shown in Table 4. In the low-rise village house, the high standardized village house type was assembled.

TABLE 4
Statistics on the number of the modular walls

| | | Number of modules | Number of modules |
|---|---|---|---|
| Module number | | on the first floor | on the second floor |
| W-1 | W-1a | 22 | 13 |
| | W-1b | 13 | 7 |

| | | |
|---|---|---|
| W-3 | 7 | 3 |
| W-7 | 5 | 4 |

| | |
|---|---|
| Total number | 77 |

Firstly, the automatic design method of the modular cold-formed thin-walled steel structure was used to calculate the required shear wall length for this project, and the calculation details were shown in Table 5. The cladding panel was selected to be the 8 mm single-sided fiber cement board. The control of seismic conditions can be seen through the calculation in Table 5. Secondly, this project also used the manual calculation method for verification. The constant loads of all the walls, the floors, and the roofs were calculated based on the structural level and size of the actual project. The two work conditions of wind resistance and seismic conditions were also calculated, and the envelope is taken. The results show that the seismic condition plays a controlling role. The brief calculation process was shown in Table 6. Finally, the design of the shear wall based on the modular cold-formed structural system was used. As shown in FIGS. 3 and 4, all the modules without openings were shear walls, and the shear wall lengths in both X-and Y-directions were counted. The results of the shear wall lengths of the above three different calculation methods were compared and shown in Table 7.

TABLE 5
Calculation of the shear wall length
by the simplified design method

| | | Seismic | Wind resistance | |
|---|---|---|---|---|
| Calculation content | | condition | condition | |
| Parameter | | A = 96.0 | BX = 10.165 | |
| | | L = 72.5 | BY = 13.77 | |
| Checking form | Ground floor | 0.15A + 0.25L | 1.787B | |
| | Second floor | 0.05A + 0.107L | 0.893B | |
| Shear wall | Ground floor | 32.53 | X-direction | 18.16 |
| length/m | | | Y-direction | 24.61 |
| | Second floor | 12.56 | X-direction | 9.08 |
| | | | Y-direction | 12.30 |

TABLE 6
Calculation by the manual calculation method

| Seismic condition | | | Wind resistance condition | | | |
|---|---|---|---|---|---|---|
| | Ground floor | Second floor | | | Ground floor | Second floor |
| Gravity load | 961.36 | 246.91 | Wind | X-direction | 40.72 | 17.93 |
| representative | | | load | | | |
| value/kN | | | design | | | |
| Horizontal | 123.5 | 39.76 | value/kN | Y-direction | 51.19 | 19.61 |
| shear force | | | | | | |
| design | | | | | | |
| value/kN | | | | | | |
| Required | 34.55 | 11.12 | Required | X-direction | 11.01 | 4.85 |
| shear | | | shear | Y-direction | 13.84 | 5.3 |
| wall length/m | | | wall | | | |
| | | | length/m | | | |

TABLE 7
Comparison of the shear wall lengths
in different calculation methods

| | | | Required wall | Required wall |
|---|---|---|---|---|
| | Calculation | | length/m for | length/m for |
| Serial | method of the | | the ground | the second |
| number | wall length | | floor | floor |
| 1 | Simplified method | | 32.53 | 12.56 |
| 2 | Manual calculation | | 34.55 | 11.12 |
| | method | | | |
| 3 | Total length of | X- | 36.6 | 18.3 |
| | actual walls | direction | | |
| | without | Y- | 27.88 | 14.64 |
| | openings | direction | | |

As shown in Table 7, (1) the shear wall length calculated using the simplified method was closer to the manual calculation results, with a difference of about 5.85%, further verifying the feasibility of the method of the present disclosure. (2) For the required shear wall length of the ground floor, the results of the simplified method were slightly smaller than that of the manual calculation, the main reason was that there was large difference in the plane area of the first floor and the second floor of the project. Although A in Table 1 was the average floor area and relatively close to the actual representative value of gravity load, there was still a certain degree of error. When the area of the upper floor was significantly smaller than that of the ground floor, the shear wall length of the ground floor of the simplified method should be enlarged as appropriate. (3) Using the method of the present disclosure, the shear wall length in the X-direction was satisfied and surplus, as shown in the flow chart in FIG. 2, optimization could be performed, or no modification was made. However, the shear wall length in the Y-direction of the bottom floor was not satisfied, in one method, the single-sided cladding panel of the wall was changed into the double-sided cladding panel to increase the shear bearing capacity; or in another method, the cladding panel type was changed by choosing cladding panels that had higher shear bearing capacity than the 8 mm single-sided fiber cement board, such as oriented strand board or steel plate.

The automatic design method of a modular cold-formed thin-walled steel structure is processed by an automatic design equipment of a modular cold-formed thin-walled steel structure.

The automatic design equipment of a modular cold-formed thin-walled steel structure includes: a processor (such as Central Processing Unit, CPU), a communication bus, an input port, an output port, and a memory. Among them, the communication bus is used to achieve connection communication between these components; the input port is used for data input; and the output port is used for data output, and the memory can be high-speed RAM memory or non volatile memory, such as disk memory, non-transitory computer-readable storage medium. Optionally, memory is a storage device independent of the aforementioned processor.

The memory, as a non-volatile readable storage medium, may include an operating system, network communication module, application program module, and a program for automatic designing a modular cold-formed thin-walled steel structure. The network communication module is mainly used to connect to servers and communicate data with them; and processor is used to call the program to process the method stored in memory, and execute all steps of the automatic design method of a modular cold-formed thin-walled steel structure mentioned above.

Described above are merely preferred embodiments of the disclosure, which are not intended to limit the disclosure. It should be understood that any modifications and replacements made by those skilled in the art without departing from the spirit of the disclosure should fall within the scope of the disclosure defined by the appended claims.

1. An automatic design method of a modular cold-formed thin-walled steel structure, performed by an automatic design system comprising a processor and a memory. wherein the processor is configured for:
(a) obtaining a minimum length of a first shear wall from a pre-designed simplified seismic design calculation table stored in the memory according to a number of floors of a to-be-designed building, a seismic fortification intensity, and a type of cladding panels of the to-be-designed building;
(b) determining a length of a shear wall without a door opening or a window opening, which is an actual length of the shear wall;
(c) comparing the minimum length of the first shear wall with the actual length of the shear wall:
if the actual length of the shear wall is less than or equal to the minimum length of the first shear wall, a shear bearing capacity does not meet requirements, the shear bearing capacity is increased by at least one of:
(1) adjusting a household arrangement, and adding a new shear wall; (2) changing a single-side cladding panel of the shear wall to a double-side cladding panel without changing the household arrangement; and (3) changing the type of cladding panels, and choosing a cladding panel material with higher shear bearing capacity:
if the actual length of the shear wall is greater than the minimum length of the first shear wall, the shear bearing capacity meets the requirements, and a final length of the shear wall is obtained;
(d) generating a design file of the modular cold-formed thin-walled steel structure according to the final length of the shear wall;
wherein according to an average floor area and an average plane wall length of the to-be-designed building, a total structural equivalent gravity load is calculated by using a bottom shear method; according to the total structural equivalent gravity load, the minimum length of the first shear wall is calculated;
the minimum length of the first shear wall is calculated through steps of:
summarizing typical structural levels of a cold-formed system; and taking a floor constant load of 2.0 kN/m², a wall constant load of 1.5 kN/m², and a floor height of 3 m, wherein a gravity load of a second floor of the to-be-designed building is 3A+4.5L in kN; A represents the average floor area of the to-be-designed building, and A=a building area/the number of floors; L represents the average plane wall length, and a unit is m, and L=(a sum of plane wall lengths of the floors of the to-be-designed building)/(the number of floors);
based on the bottom shear method, obtaining the total structural equivalent gravity load as Geq=5.95A+9.5625L, and obtaining a standard value of a total structural horizontal seismic action as FEK=0.275A+0.442L, and a standard value of a horizontal seismic action of the second floor as F2=0.138A+0.197L;
in a seismic fortification zone, expressing a shear force per unit length of the shear wall as
$${S}_{E} = \frac{{V}_{j}}{{L}_{j}} \leq {S}_{h} / {r}_{RE} ,$$
wherein Vⱼ represents a horizontal shear force beared by the shear wall; Lⱼ represents the length of the shear wall; Sₕ represents a design value of a shear bearing capacity per unit length of the shear wall, and r_{RE} represents a seismic coefficient of the shear bearing capacity; expressing the length of the shear wall as
$${L}_{j} \geq {r}_{RE} \frac{{V}_{j}}{{S}_{h}} ;$$
wherein the horizontal shear force Vⱼ beared by the shear wall is obtained by multiplying the standard value F₂ of the horizontal seismic action by a partial coefficient of the design value; and according to the types of cladding panels, obtaining Sₕ per unit length of a single-sided oriented strand board, and considering an amplification coefficient stipulated in the technical specification, thereby obtaining the minimum length of the first shear wall by a formula expressed as
$${L}_{j} = {r}_{RE} \frac{{V}_{j}}{{S}_{h}} ;$$
and
wherein based on the minimum length of the first shear wall under different seismic fortification intensity, the number of floors, and the cladding panels, the pre-designed simplified seismic design calculation table is constituted.

2. The automatic design method of claim 1, wherein the pre-designed simplified seismic design calculation table comprises the seismic fortification intensity, the number of floors, the type of cladding panels, and the minimum length of the first shear wall; and the minimum length of the first shear wall is a sum of the average floor area multiplied by a first coefficient and the average plane wall length multiplied by a second coefficient.

3. (canceled)

4. The automatic design method of claim 1, further comprising:
obtaining the number of floors of the to-be-designed building, a wind pressure, and a type of cladding panels of the to-be-designed building;
obtaining a minimum length of a second shear wall from a pre-designed simplified wind-resistant design calculation table;
based on the minimum length of the first shear wall and the minimum length of the second shear wall, obtaining the minimum length of the shear wall; and
comparing the minimum length of the shear wall with the actual length of the shear wall to obtain the final length of the shear wall.

5. The automatic design method of claim 4, wherein the step of “based on the minimum length of the first shear wall and the minimum length of the second shear wall, obtaining the minimum length of the shear wall” comprises: obtaining envelope values of the minimum length of the first shear wall and the minimum length of the second shear wall.

6. The automatic design method of claim 4, wherein the pre-designed simplified wind-resistant design calculation table comprises the wind pressure, the number of floors, the type of cladding panels, and the minimum length of the first shear wall; and the minimum length of the second shear wall is a product of multiplying a third factor with the width of the to-be-designed building in a direction of the shear wall.

7. (canceled)

8. An automatic design device, comprising:
at least one processor;
a memory; and
a program instruction;
wherein the memory is communicatively connected to the at least one processor; the program instruction is stored in the memory and is configured to be executed by the at least one processor, and the at least one processor is configured to execute the program instruction to implement the automatic design method of claim 1.
